(19) United States
(12) Patent Application Publication
(10) Pub. No.: US 2015/0243511 A1
(43) Pub. Date: Aug. 27, 2015

(54) METHOD OF FORMING PATTERN AND PHOTO MASK USED THEREIN

(71) Applicant: Kabushiki Kaisha Toshiba, Minato-ku (JP)

(72) Inventor: Ryota OHNUKI, Yokkaichi-shi (JP)

(73) Assignee: Kabushiki Kaisha Toshiba, Minato-ku (JP)

(21) Appl. No.: 14/276,034

(22) Filed: May 13, 2014

Related U.S. Application Data
(60) Provisional application No. 61/943,060, filed on Feb. 21, 2014.

(51) Int. Cl. H01L 21/308; G03F 1/42; H01L 21/02

(52) U.S. Cl. CPC H01L 21/3086; H01L 21/3081; H01L 21/02271; G03F 1/42

(57) ABSTRACT

According to one embodiment, there is provided a transferring method in which, from a mask pattern including a first region of a first pattern that is surrounded by a first space and a second region of a second pattern that is surrounded by a space wider than the first space, only the first pattern is selectively transferred on a mask layer. After transferring only the first pattern on the mask layer using the mask pattern and leaving a mask layer in the second region, a pattern on the mask layer is transferred on a film to be processed.

### CROSS-REFERENCE TO RELATED APPLICATIONS

This application is based upon and claims the benefit of priority from Provisional U.S. Patent Application No. 61/943,060, filed on Feb. 21, 2014; the entire contents of all of which are incorporated herein by reference.

### FIELD

Embodiments described herein relate to a method of forming a pattern and a photo mask used therein, and particularly relate to an RIE (Reactive Ion Etching) method for forming a pattern in which different space widths are present.

### BACKGROUND

Conventionally, there has been disclosed techniques of performing lithographic processing on each region having different pattern size separately according to each pattern size. In these techniques, when RIE is performed on these regions without additional processes, all films to be processed in mask-opened regions, which are exposed from mask-pattern, are processed. Therefore, in these processes, lithography, in which patterns that have to be kept unprocessed are coated with a mask material, is required

However, due to the recent minitualization, in such conventional techniques, requirement for more accurate alignment causes problems of difficulty of mask material formation and increasing cost.

### BRIEF DESCRIPTION OF THE DRAWINGS

FIG. 1A to FIG. 1C are process cross-sectional views schematically illustrating a method of forming a pattern according to a first embodiment;

FIG. 2 is a schematic diagram of an etching device used in the first embodiment;

FIG. 3 is a timing chart illustrating an ON/OFF timing of a bias voltage;

FIG. 4A and FIG. 4B are diagrams illustrating a mechanism of an etching reaction on a surface of a substrate at a bias “ON” period and a bias “OFF” period, respectively;

FIG. 5 is a graph showing a result of measuring a relationship between an aspect ratio and an etching rate of a pattern;

FIG. 6 represents measurement values showing a result of measuring a relationship between an aspect ratio of a pattern and an etching rate;

FIG. 7 illustrates etching conditions of a first etching process in the first embodiment;

FIG. 8A to FIG. 8D are process cross-sectional views schematically illustrating a method of forming a pattern according to a second embodiment;

FIG. 9A to FIG. 9D are process cross-sectional views schematically illustrating a method of forming a pattern according to a third embodiment;

FIG. 10 illustrates etching conditions of a first etching process in the third embodiment;

FIG. 11A is a schematic explanatory diagram of relevant parts of a photo mask according to a fourth embodiment, FIG. 11B is a cross-sectional view of B-B of FIG. 11A, and FIG. 11C is a schematic explanatory diagram of a cross section of relevant parts illustrating an original photo mask; and

FIG. 12A to FIG. 12E are process cross-sectional views schematically illustrating a method of forming a pattern according to a comparative example.

### DETAILED DESCRIPTION

According to one embodiment, there is provided a transferring method in which, from a mask pattern including a first region of a first pattern that is surrounded by a first space and a second region of a second pattern that is surrounded by a space wider than the first space, only the first pattern is selectively transferred on a mask layer. In the transferring method, first, a first etching step of transferring the first pattern on the mask layer selectively by performing etching the first and second patterns as a mask, and leaving a mask layer in the second region is performed. Thereafter, as a second etching step, a pattern transferred on the mask layer is transferred on a processing-target film.

Embodiments of a method of forming pattern and photo mask used therein will be explained in following paragraphs in detail by referring to the accompanying drawings. The present invention is not limited to the following embodiments.

### First Embodiment

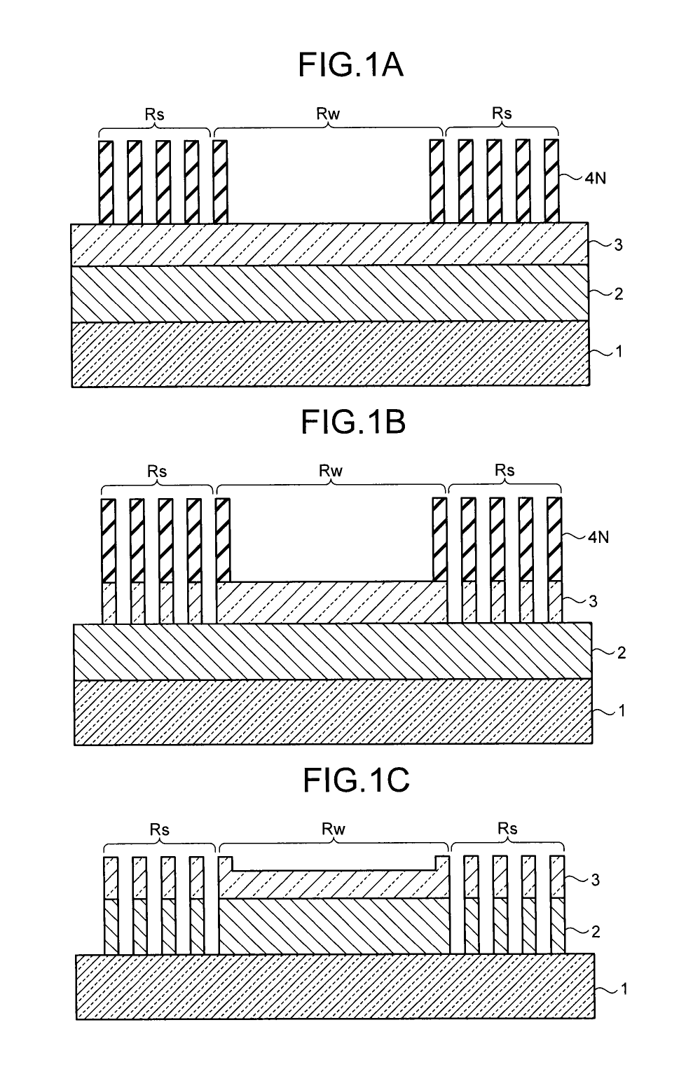

FIG. 1A to FIG. 1C are process cross-sectional views schematically illustrating a method of forming a pattern according to the present embodiment. In the present embodiment, a single-crystal silicon substrate is used as a substrate 1, a W layer as a film 2 to be processed and a mask layer 3 made of amorphous silicon (a-Si) are stacked on the substrate 1, a mask pattern of silicon nitride (SiN) film 4N which consists of more than one patterns of different space width is formed on top of the mask layer 3, and this mask pattern is transferred on the film 2 to be processed. The mask pattern consists of a first region R_{S} including a first pattern that is surrounded by a first space as a finer space and a second region R_{W} including a second pattern that is surrounded by a wider space than the first space. The transfer process of the mask pattern includes a first etching process for transferring only the first pattern on the mask layer 3 by etching the first and second patterns as a mask while leaving the mask layer 3 in the second region R_{W} and a second etching process for transferring the mask layer 3 on the film 2 to be processed.

First, a W layer as the film 2 to be processed is formed by a CVD method on the substrate 1 of a single-crystal silicon substrate. Subsequently, an a-Si layer is formed as the mask layer 3 also by the CVD method. Thereafter, the silicon nitride film 4N is formed by the CVD method on top of the a-Si layer and then a mask pattern is formed by photolithography (FIG. 1A). This mask pattern includes the first region R_{S} of a first pattern that is surrounded by a finer space and the second region R_{W} of a second pattern that is surrounded by a wider space.

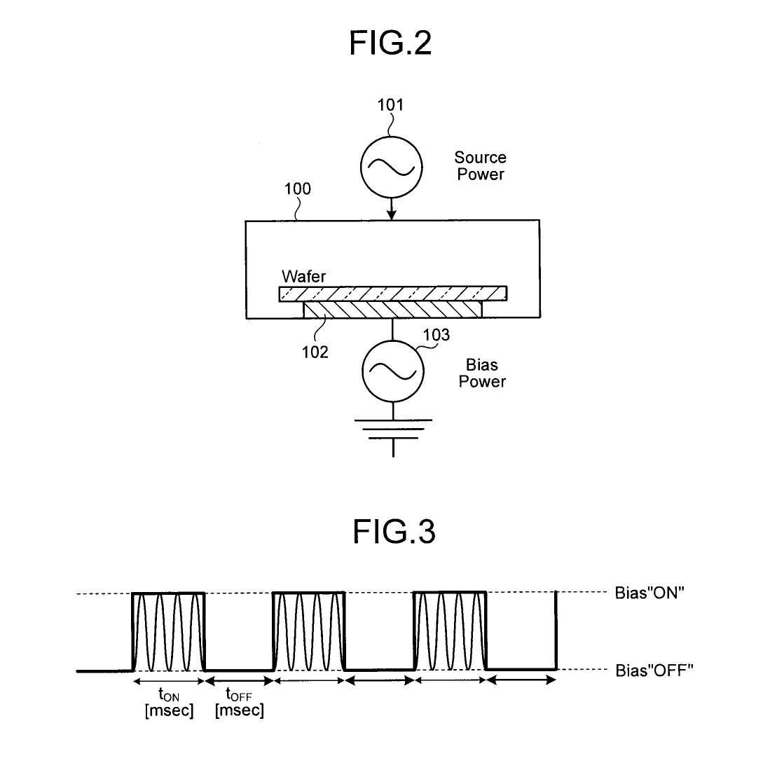

Thereafter, the first etching process is performed under an etching condition in which etching is not performed in the second region R_{W} of a second pattern that is surrounded by a wider space (FIG. 1B). By using chlorine gas Cl₂ that is highly reactive to silicon under high pressure, in the first etching process, a reaction product is held in a chamber Therefore, etching is not performed in the second region R_{W} of a second pattern that is surrounded by a wider space, and etching selectively progresses only in the first region R_{S} of a first pattern that is surrounded by a finer space. As shown in the schematic diagram of an etching device in FIG. 2, a power source 101 and an electrode that also functions as a substrate support plate 102 are included in a chamber 100, and a wafer (the substrate 1) is set on the substrate support plate 102. It is also configured that a bias voltage can be applied from a bias power source 103.

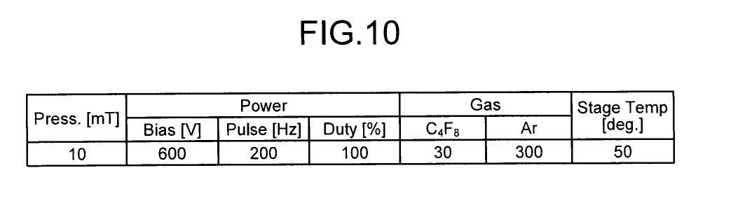

In this manner, as shown in FIG. 10, the film 2 to be processed (W) is etched by the second etching process and the patterning of the film 2 is completed. At this time, in the second region R_{W}, while a region not coated by the silicon nitride film 4N is etched to some extent, the most part of the region is left as it is.

FIG. 3 is a timing chart illustrating an ON/OFF timing of a bias voltage. As can be understood from FIG. 3, an on-pulse t_{ON} and an off-pulse t_{OFF} are alternately applied.

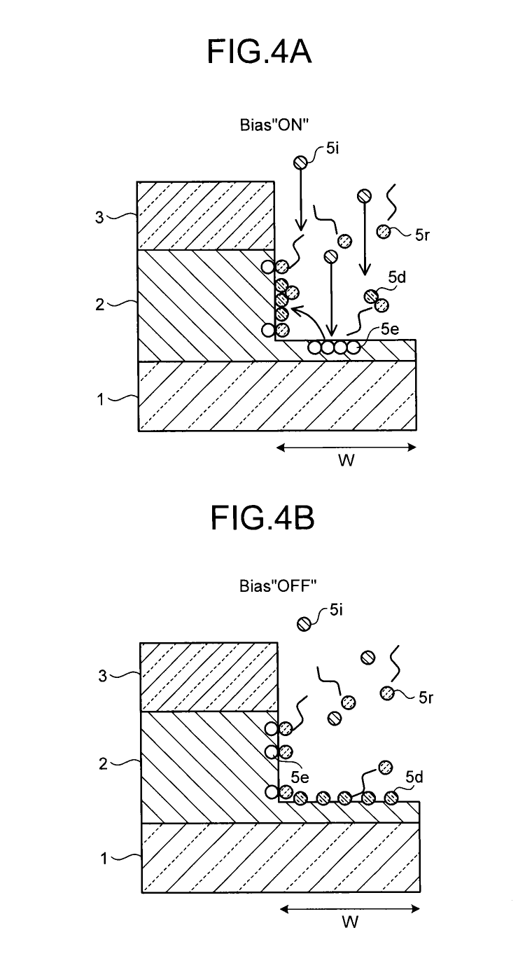

FIG. 4A and FIG. 4B are diagrams illustrating a mechanism of an etching reaction on a surface of the substrate 1 at a bias “ON” period and a bias “OFF” period, respectively. FIGS. 4A and 4B are enlarged explanatory diagrams of FIG. 1B, and similarly to FIG. 1B, FIGS. 4A and 4B schematically illustrate a surface of a W film (a metal film) as the film 2 to be processed formed on the substrate 1 at the time of patterning the surface with a pattern of the mask layer 3 of an a-Si layer. When chlorine ion 5i made of Cl₂ as reactant gas or chlorine radical 5r attacks the film 2 to be processed being exposed from the pattern of the mask layer 3, the attacked film 2 to be processed is etched and becomes an etching region 5e. Meanwhile, by generating the etching region 5e, a reaction product 5d is generated. As shown in FIG. 4B, when a bias is OFF, the reaction product 5d is deposited on a surface of the film 2 to be processed. Accordingly, in case that the bias “OFF” period is long, the reaction product 5d is deposited and etching is stopped in the wider space. As a duty value of an ON ratio in the ON/OFF of an applied bias is set equal to or lower than 30%, the reaction product 5d is deposited efficiently. Further, because a sparse pattern is proportional to the amount of the reaction product 5d and the amount of deposition is larger in the region of the sparse pattern, the region of the sparse pattern is covered with the reaction product 5d and etching is stopped, so that only a dense pattern can be processed. In this manner, by using highly reactive gas as etching gas, for example chlorine gas such as chlorine-containing gas, the etching rate is high and the reaction product is formed in high speed, and thus the amount of deposition of the reaction product in the region of the sparse pattern is increased and etching is stopped. Particularly, deposition effects become higher as etching is performed under a pulse voltage with a small duty ratio. Therefore, as the present embodiment utilizes this phenomenon and selects etching conditions, conditions in which etching is stopped in the region of the sparse pattern are used.

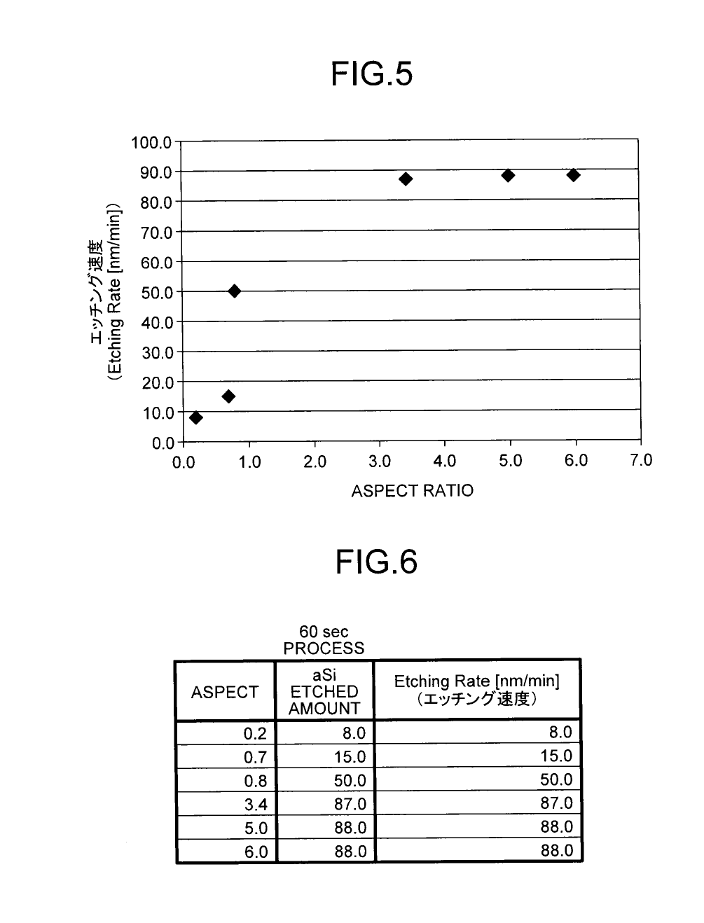

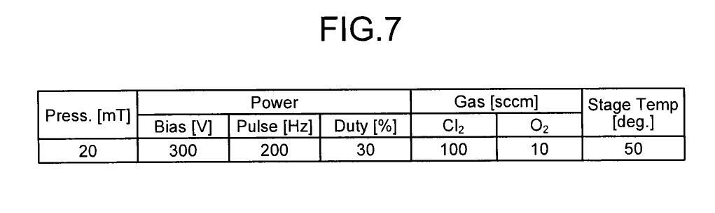

FIG. 5 is a graph showing a result of measuring a relationship between an aspect ratio and an etching rate of a pattern of an obtained mask layer (a-Si) 3, and FIG. 6 illustrates the measured values. FIG. 7 illustrates etching conditions of a first etching process, which are etching conditions of the a-Si as the mask layer 3. In FIG. 5, the horizontal axis represents an aspect ratio and the vertical axis represents an etching rate (nm/min). In this example, the film thickness of the metal film is made constant and the pattern size is changed. The etching conditions are set such that the pressure within a chamber is 20 mTorr, the bias is 300 V, the pulse is 200 Hz, and the duty ratio is 30%. As for the gas, chlorine gas Cl₂ is 100 sccm and O₂ is 20 sccm. The temperature of the substrate support plate 102 is 50° C. FIGS. 5 and 6, shows that etching remains occurs when the aspect ratio is equal to or less than 1, and when the aspect ratio is equal to or greater than 3, etching progresses until pattern is formed.

As for the pattern size, it is preferable that the space width of the second region R_{W} is equal to or larger than 105 nm. When the space width of the second region R_{W} is equal to or larger than 105 nm, the mask layer in the second region R_{W} is substantially left as it is without being etched. It is more preferable that the space width of the second region R_{W} is equal to or larger than 135 nm. When the space width of the second region R_{W} is equal to or larger than 135 nm, the space of the second region R_{W} is certainly left as it is without being etched. Meanwhile, it is found that, when the space width of the first region R_{S} is equal to or less than 40 nm, etching progresses in the first region R_{S} to certainly realize pattern formation without any unetched patterns.

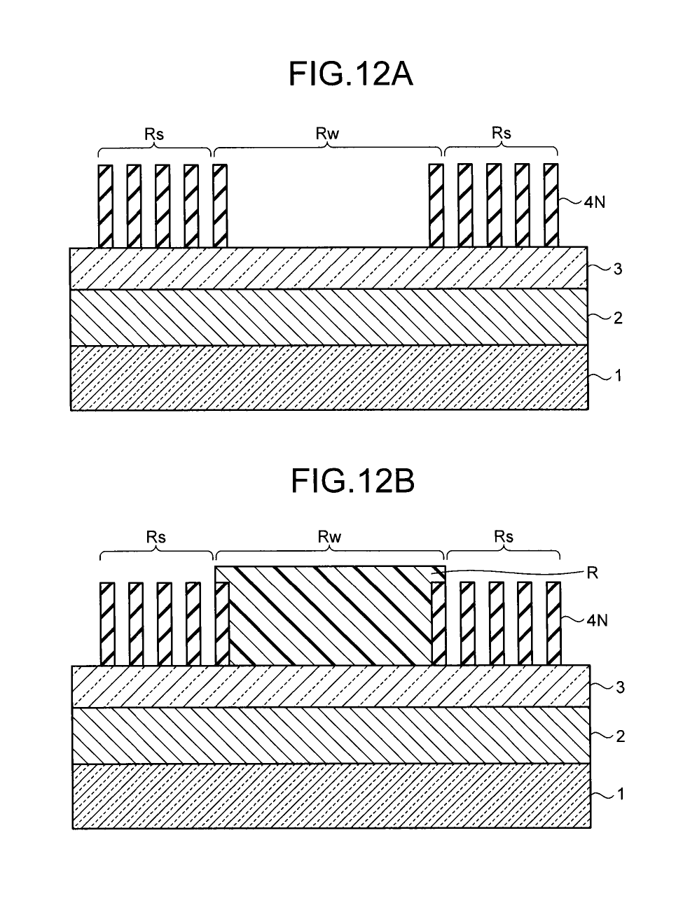

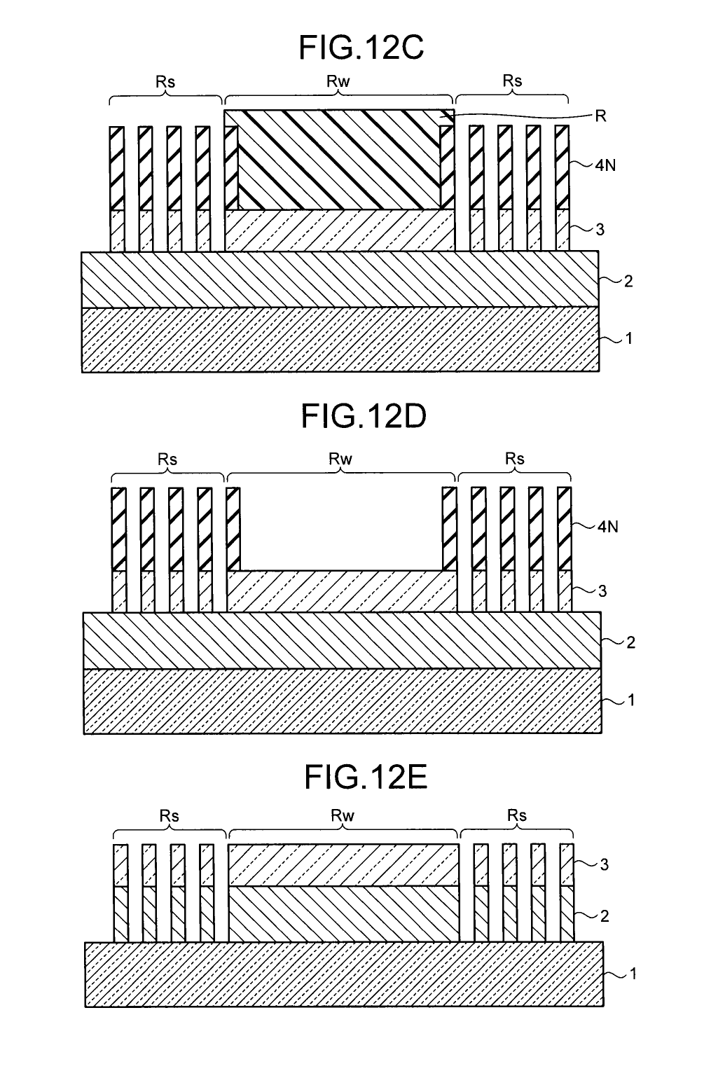

FIG. 12A to FIG. 12E are process cross-sectional views schematically illustrating a method of forming a pattern of a W film according to a comparative example. In the case of the comparative example, as shown in FIG. 12A, a mask pattern of the silicon nitride film 4N having the first region R_{S} as a narrower space region and the second region R_{W} as a wider space region are patterned. In this case, as shown in FIG. 12B, the second region R_{W} as a wider space region is coated with a resist R, and as shown in FIG. 12C, the first region R_{S} as a narrower space region is patterned using fluorine gas. Thereafter, as shown in FIG. 12D, the resist R is removed. Subsequently, as shown in FIG. 12E, the film 2 to be processed is patterned. FIG. 12E illustrates a state after the film 2 to be processed has been patterned. In this case, not only that the cost for performing immersion lithography is increased, but also that the pattern of the resist R may be misaligned. Even slight misalignment of the pattern of the resist R due to the misaligned of the pattern, there may be an incident of etching remains or an incident that a part supposed to remain unetched may be etched, and these incidents cause a characteristic change in the device and this leads to a very serious state.

For example, when a trench is formed in the second region while leaving a selected gate part as the first region, due to this misalignment, the selected gate is unexpectedly etched or kept unetched in the trench, it causes serious consequences on the device characteristics. Also from these comparisons, it is shown that simple and highly accurate pattern formation can be achieved by the method of the present embodiment.

### Second Embodiment

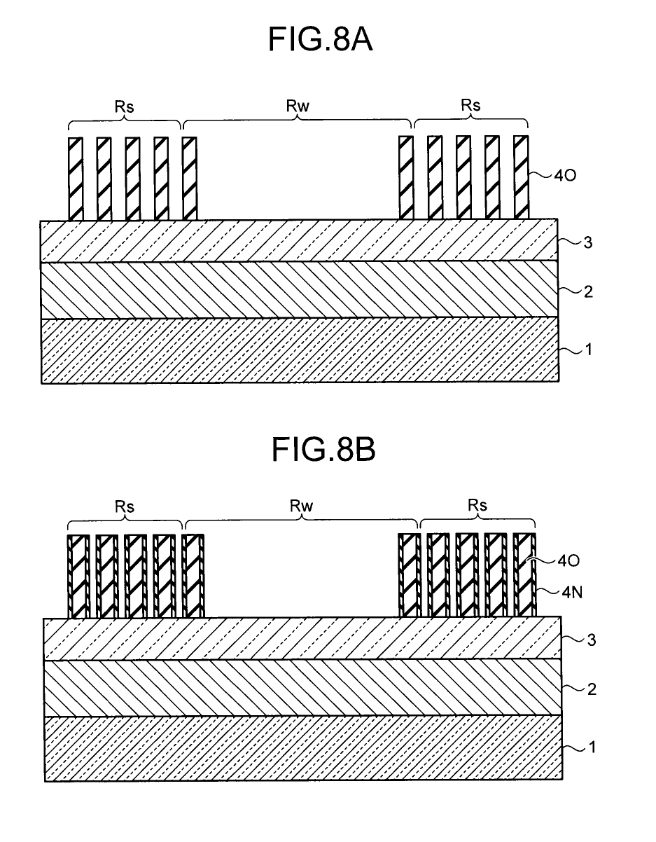

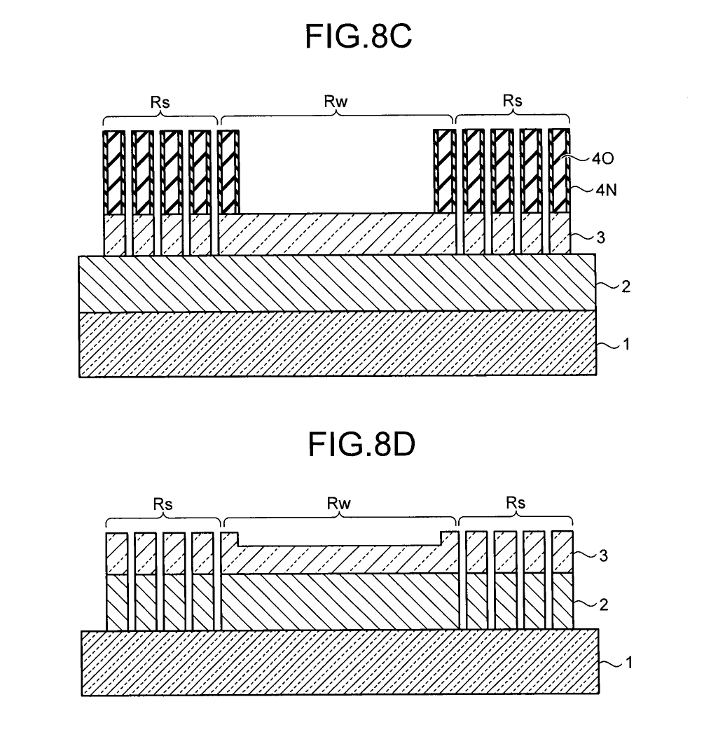

FIG. 8A to FIG. 8D are process cross-sectional views schematically illustrating a method of forming a pattern according to the present embodiment. In the present embodiment, similar to the first embodiment, patterning on a metal film as the film 2 to be processed is performed; however, the present embodiment is different from the first embodiment in a feature of using a method of forming the first region R_{S} of a first pattern surround by a space so as to downscale the first region R_{S} beyond a resolution limit of photolithography. That is, it is a method of further downscaling a mask pattern after forming the mask pattern formed of silicon oxide films 40 by photolithography. In the present embodiment, by “sidewall leaving” using the silicon nitride film 4N, a sidewall film of the silicon nitride film 4N on a sidewall of the first pattern of the silicon oxide films 40 in a finer space region is formed on the mask pattern formed of the silicon oxide films 40 so as to further downscale a finer space width. Except for the feature that a sidewall film is formed in this manner to further downscale a finer space width, the present embodiment is exactly the same as the first embodiment.

Also in the present embodiment, a single-crystal silicon substrate is used as the substrate 1, and a W layer as the film 2 to be processed and the mask layer 3 made of amorphous silicon (a-Si) are formed on the substrate 1. A mask pattern constituting the first region R_{S} with a finer width has the silicon oxide films 40 which consists of more than one patterns of different space width and the silicon nitride (SiN) film 4N formed on the sidewalls of the silicon oxide films 40. The mask pattern is formed on top of the mask layer 3, and this mask pattern is transferred on the film 2 to be processed. In this manner, the mask pattern includes the first region R_{S} of the first pattern that is surrounded by a space finer than that of the first embodiment and the second region R_{W} of a second pattern that is surrounded by a wider space. Furthermore, similar to the first embodiment, the transfer process of the mask pattern includes a first etching process of transferring only the first pattern on the mask layer 3 by etching the first and second patterns as a mask, and leaving the mask layer 3 in the second region R_{W} and a second etching process of performing pattern transfer of the mask layer 3 on the film 2 to be processed.

These processes are explained in following paragraphs in detail by referring to FIGS. 8A to 8D. First, a W layer as the film 2 to be processed is formed by the CVD method on the substrate 1 of a single-crystal silicon substrate. Subsequently, an a-Si layer is formed as the mask layer 3 also by the CVD method. Thereafter, the silicon oxide films 40 are formed by the CVD method on top of the a-Si layer to form a mask pattern by photolithography (FIG. 8A). This mask pattern includes the first region R_{S} of the first pattern that is surrounded by a finer space and the second region R_{W} of the second pattern that is surrounded by a wider space.

Further, as shown in FIG. 8B, the silicon nitride film 4N are formed by the CVD method, and by leaving a sidewall film on the sidewalls of the silicon oxide films 40 by anisotropic etching, the first region R_{S} is formed to have a finer space width.

Thereafter, similar to the first embodiment, the first etching process is performed under an etching condition in which etching is not performed in the second region R_{W} of a second pattern that is surrounded by a wider space (FIG. 8C). Similar to the first embodiment, By using chlorine gas Cl₂ that is highly reactive to silicon under high pressure, in the first etching process, a reaction product is held in a chamber. It is known that deposition effects particularly become higher as etching is performed under a pulse voltage with a small duty ratio. Therefore, by selecting etching conditions, etching is not performed in the second region R_{W} of a second pattern that is surrounded by a wider space, and etching progresses selectively only in the first region R_{S} of a first pattern that is surrounded by a finer space.

In this manner, as shown in FIG. 8D, the film 2 to be processed (W) is etched by the second etching process and the patterning is finished.

### Third Embodiment

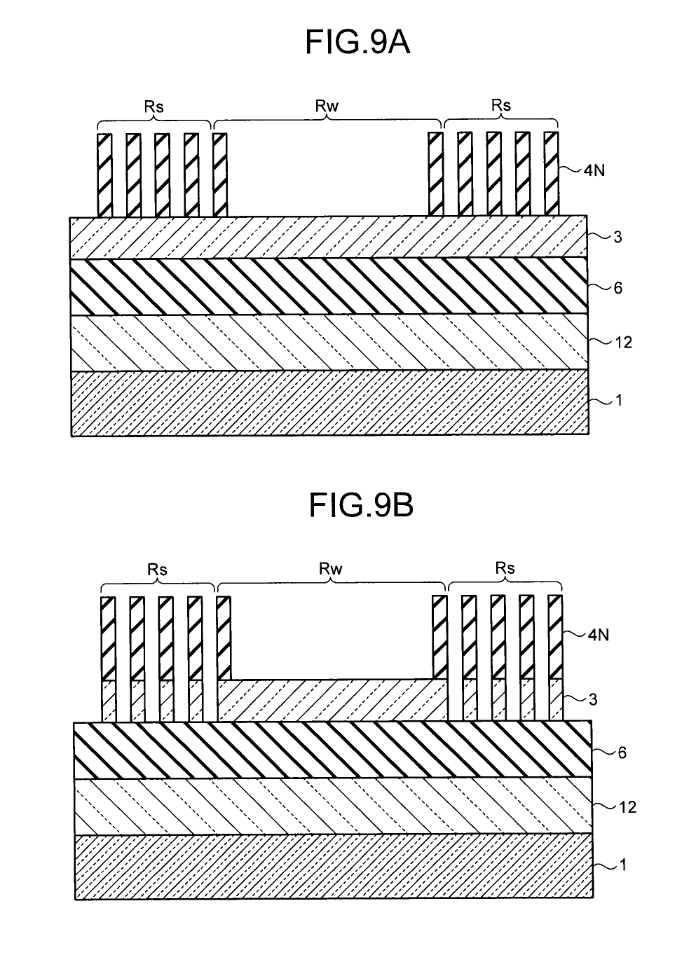

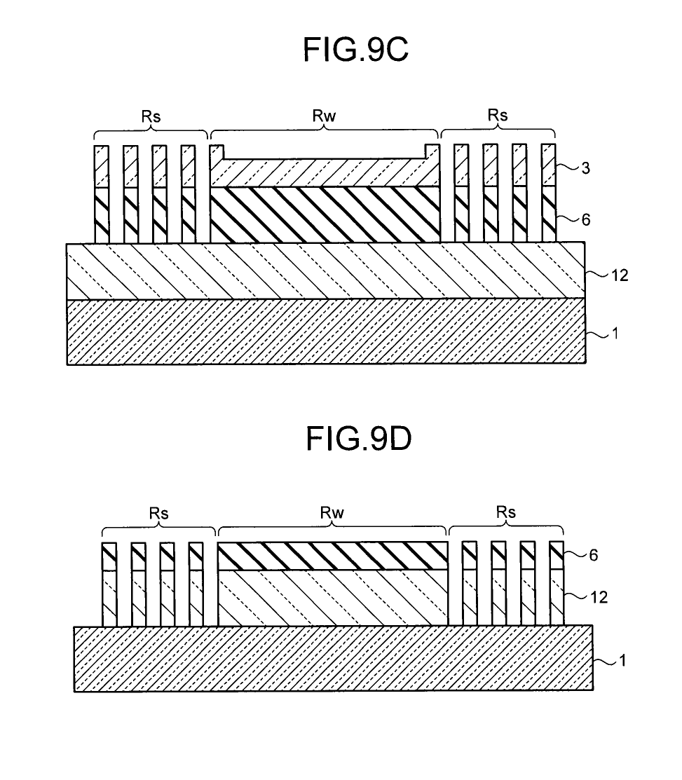

FIG. 9A to FIG. 9D are process cross-sectional views schematically illustrating a method of forming a pattern according to the present embodiment. The present embodiment is characterized such that because an a-Si layer as the mask layer 3 does not have etching-selectivity to a doped amorphous silicon layer as a film 12 to be processed, as a second mask layer having etching-selectivity to both layers, a mask auxiliary layer 6 of a silicon oxide film is formed to provide a dual mask configuration. Similarly to the first embodiment, in the present embodiment, the mask pattern of an a-Si layer is used to perform patterning on the film 12 to be processed. however, the present embodiment is different from the first embodiment in the feature that the mask layer has a dual mask configuration including the mask layer 3 and the mask auxiliary layer 6.

FIG. 10 illustrates etching conditions of the mask auxiliary layer 6 of a silicon oxide film in a first etching process in the present embodiment. In the present embodiment, features other than having mask auxiliary layer 6 are exactly the same as those of the first embodiment. That is, in a transferring method of the present embodiment, a single-crystal silicon substrate is used as the substrate 1, and a doped amorphous silicon layer as the film 12 to be processed, the mask auxiliary layer 6, and the mask layer 3 made of amorphous silicon (a-Si) are formed on the substrate 1 in this order. Subsequently, a mask pattern of the silicon nitride film 4N which consists of the first region R_{S} with a very smaller space width and the second region R_{W} with a larger space width is formed on top of the mask layer 3, and this mask pattern is transferred on the film 12 to be processed. The mask pattern includes the first region R_{S} of a first pattern that is surrounded by a finer space and the second region R_{W} of a second pattern that is surrounded by a wider space. The transfer process of the mask pattern includes a first etching process of transferring only the first pattern on the mask layer 3 by etching the first and second patterns as a mask, and leaving the mask layer 3 in the second region R_{W} and a second etching process of performing pattern transfer of a pattern of the mask auxiliary layer 6 on the film 12 to be processed after performing a third etching process of performing pattern transfer of the mask layer 3 on the mask auxiliary layer 6. Other processes are identical to those of the first embodiment.

These processes are explained in detail by referring to FIGS. 9A to 9D. First, a doped amorphous silicon layer as the film 12 to be processed is formed by the CVD method on the substrate 1 of a single-crystal silicon substrate. Subsequently, a silicon oxide layer is formed as the mask auxiliary layer 6 also by the CVD method. Thereafter, an a-Si layer is formed as the mask layer 3 on top of the silicon oxide layer. Further, the silicon nitride film 4N is formed by the CVD method on top of the a-Si layer to form a mask pattern by photolithography (FIG. 9A). This mask pattern includes the first region R_{S} of a first pattern that is surrounded by a finer space and the second region R_{W} of a second pattern that is surrounded by a wider space.

Thereafter, the first etching process is performed under an etching condition in which etching stop occurs in the second region R_{W} of a second pattern that is surrounded by a wide space (FIG. 9B). By using chlorine gas Cl₂ that is highly reactive to silicon under high pressure, in the first etching process, a reaction product is held in a chamber. Therefore, etching is not performed in the second region R_{W} of a second pattern that is surrounded by a wider space, and etching progresses selectively only in the first region R_{S} of a first pattern that is surrounded by a finer space.

In this manner, as shown in FIG. 9C, a pattern of the mask layer is transferred on the mask auxiliary layer 6 by the third etching process. In this case, because a silicon oxide layer is used as the mask auxiliary layer 6, etching is performed as C₄F₈+Ar is used as etching gas. When a silicon nitride layer is used as the mask auxiliary layer 6, etching is performed as CH₃F or similar gas and the like is used as etching gas.

Finally, as shown in FIG. 9D, a doped amorphous silicon layer as the film 12 to be processing is etched by the second etching process and the patterning is completed.

As described above, according to the third embodiment, when the film 12 to be processed is processed by using a mask layer, a reaction product is used by performing etching under conditions of including Cl₂ and having a low bias (BiasRF) and a low duty ratio (BiasRF On ratio), only line and space pattern with narrower space width is processed, and gaps between select gates with a wider space width can be left unetched by etching stop.

The present embodiment enables efficient patterning even when patterning is performed on a silicon semiconductor layer such as a doped amorphous silicon layer, because the mask auxiliary layer 6 made of silicon oxide is interposed.

### Fourth Embodiment

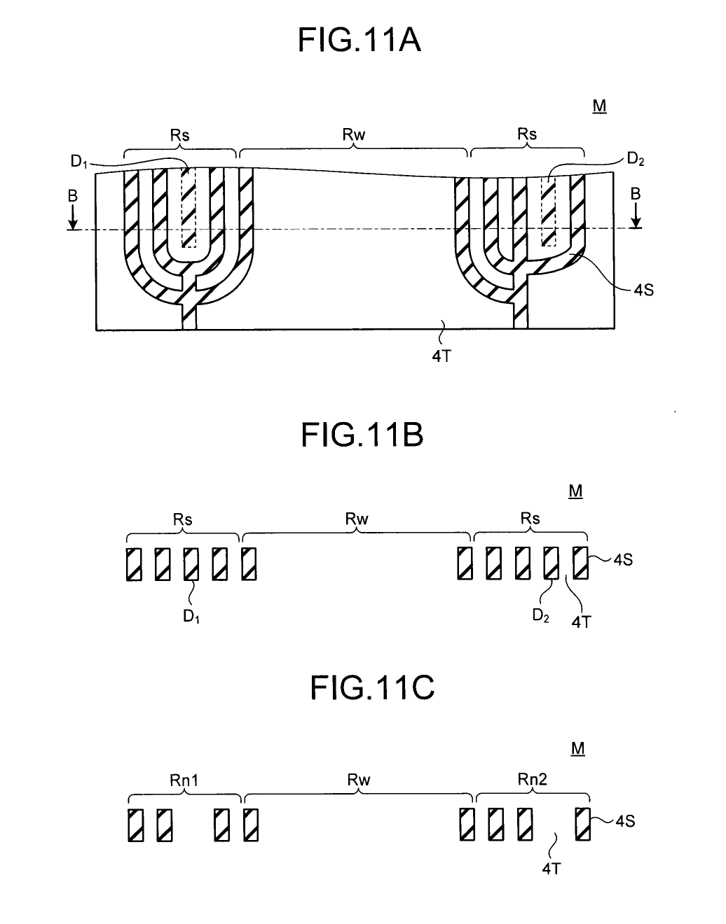

FIG. 11A is a schematic explanatory diagram of relevant parts of a photo mask according to a fourth embodiment, FIG. 11B is a cross-sectional view of B-B of FIG. 11A, and FIG. 11C is a schematic explanatory diagram of a cross section of relevant parts illustrating an original photo mask. The photo mask M is a photo mask for forming a mask pattern (for example, the silicon nitride films 4 in the first to third embodiments) to form the mask layer 3. For example, the photo mask M has light-shielding patterns 4S formed on a transparent glass substrate (not shown) and parts other than the light-shielding patterns 4S constitute a transparent region 4T. This photo mask is used when a mask pattern is patterned by using a positive resist, and when a mask pattern is patterned by using a negative resist, a negative photo mask in which the light-shielding patterns 4S and the transparent region 4T are reversed, is used.

As shown in FIG. 11C, when a photo mask is constituted by regions Rₙ₁ and Rₙ₂ including a space with an intermediate width and the second region R_{W} of a wide pattern, in the present embodiment, by inserting dummy patterns D1 and D2 as shown in FIGS. 11A and 11B, the space with an intermediate width is eliminated.

The present embodiment configures the photo mask M that is constituted by the first region R_{S} of a first pattern that is surrounded by a finer space and the second region R_{W} of a second pattern that is surrounded by a wider space Similar to the mask pattern, the dummy patterns D1 and D2 are made of the light-shielding patterns 4S of a light-shielding material such as a chrome layer, and the dummy patterns D1 and D2 are formed to be isolated patterns. Therefore, for example, a formed mask pattern of a silicon nitride film is transferred on an a-Si layer as the mask layer 3. The mask pattern is further transferred on a film to be processed. In this case, similar to the surface of the photo mask, the dummy patterns constitute a floating pattern including a pattern of an isolated film to be processed.

In the configuration described above, because the configuration does not include a space with an intermediate width, etching remains do not occur and highly accurate pattern formation can be achieved. A pattern surrounded by a highly accurate finer space can be formed without separately forming another mask pattern in the second region R_{W} with a wider space. A space with width W (W<a_{S}) that can be completely removed and a space with width W (W<a_{W}) that can be left as it is, are determined in advance according to etching conditions at the time of masking formation. Thereafter, by only carrying out a layout design while drawing patterns and inserting dummy patterns so as to set the space width of the first region R_{S} surrounded by a finer space as W<a_{S} and the space width of the second region R_{W} with a wider space as W<a_{W}, highly accurate patterning is easily achieved. As described above, because there is no region including a space with an intermediate width, that is, the space width W is a_{S}<W<a_{W}, highly accurate pattern formation can be achieved while there is no etching remains and the second region R_{W} with a wider space is left as it is.

By providing a configuration in which the first region R_{S} includes a dummy pattern and the space width is constant, it becomes possible to form a pattern with a highly accurate finer space.

For example, the etching conditions are set such that the pressure within a chamber is 20 mTorr, the bias is 300 V, the pulse is 200 Hz, and the duty ratio is 30%. As for the gas, chlorine gas Cl₂ is 100 sccm and O₂ is 20 sccm. The temperature of the substrate support plate 102 is 50° C. In this case, a photo mask is constituted by the second region R_{W} where the aspect ratio is equal to or less than 1 and having a wider space and the first region R_{S} where the aspect ratio is equal to or greater than 3 and being surrounded by a finer space. In this manner, etching is not performed and remains as it is in the second region R_{W} where the aspect ratio is equal to or less than 1, and in the second region R_{W} where the aspect ratio is equal to or greater than 3, etching progresses until pattern is formed.

Further, in the case of the etching conditions described above, the space width of the second region R_{W} with a wider space is preferably equal to or larger than 105 nm and equal to or less than 135 nm. Meanwhile, the space width of the first region R_{S} that is surrounded by a finer space is preferably equal to or less than 40 nm. When such a configuration is applied, in commonly used etching conditions, pattern is formed sharply and a pattern is left as it is in the second region R_{W} with a wider space.

A photo mask used in an etching process using chlorine gas and a method of forming a pattern using the photo mask have been described in the first to fourth embodiments. The etching conditions in the etching process can be changed. Further, although a lower limit value of a space width to be left and an upper limit value of a space width to be ectchedvaries according to the etching conditions, highly reliable pattern formation can be achieved by determining layouts and etching conditions upon detection of these values in advance.

Further, as for formation of a mask pattern for patterning the film 2 to be processed, scope of this invention is not limited only to photolithography, but it is also applicable to other methods including laser drawing and similar technologies.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of forming a pattern comprising:
forming a mask layer on a substrate including a film to be processed;
patterning a mask pattern on the mask layer, the mask pattern including a first region of a first pattern that is surrounded by a first space and a second region of a second pattern that is surrounded by a space wider than the first space;
transferring the first pattern selectively on the mask layer by performing etching the first and second patterns as a mask, and leaving a mask layer in the second region; and
transferring a pattern of the mask layer on the film to be processed.

2. The method of forming a pattern according to claim 1, wherein
forming a mask layer is forming a dual mask layer constituted by a second mask layer and a first mask layer stacked in this order on the substrate including the film to be processed, and
the method further comprises:
patterning a mask pattern on the dual mask layer, the mask pattern including a first region of a first pattern that is surrounded by a first space and a second region of a second pattern that is surrounded by a space wider than the first space;
transferring only the first pattern on the first mask layer by performing etching the first and second patterns as a mask, and leaving the first mask layer in the second region; and
transferring a pattern on the second mask layer while using the first and second patterns as a mask, and wherein
the second mask layer has etching selectivity to the film to be processed, and
the first mask layer has etching selectivity to the second mask layer.

3. The method of forming a pattern according to claim 1, wherein a space width of the second region is equal to or larger than 105 nm.

4. The method of forming a pattern according to claim 3, wherein the space width of the second region is equal to or larger than 135 nm.

5. The method of forming a pattern according to claim 3, wherein a space width of the first region is equal to or less than 40 nm.

6. The method of forming a pattern according to claim 1, wherein the mask pattern has an aspect ratio equal to or greater than 3 in the first region, and has an aspect ratio equal to or less than 1 in the second region.

7. The method of forming a pattern according to claim 2, wherein the first mask layer is an a-Si layer, and the second mask layer is SiO₂.

8. The method of forming a pattern according to claim 1, wherein the mask layer is an a-Si layer.

9. The method of forming a pattern according to claim 1, wherein the transferring only the first pattern is using Cl₂-containing gas as etching gas.

10. The method of forming a pattern according to claim 9, wherein the transferring only the first pattern is a pulse-etching with a duty ratio equal to or less than 15%.

11. The method of forming a pattern according to claim 7, wherein the film to be processed is a silicon film.

12. The method of forming a pattern according to claim 1, wherein the film to be processed is a metal film.

13. A photo mask comprising:
a first region of a first pattern only of a space with a width narrower than a first space width; and
a second region of a second pattern only of a space with a width wider than a second space width.

14. The photo mask according to claim 13, wherein
the first and second widths are determined based on etching conditions, and
only the first pattern is transferred on a mask layer by performing etching the first and second patterns as a mask, and leaving a mask layer in the second region.

15. The photo mask according to claim 13, wherein a space width of the second region is equal to or larger than 105 nm.

16. The photo mask according to claim 15, wherein the space width of the second region is equal to or larger than 135 nm.

17. The photo mask according to claim 15, wherein a space width of the first region is equal to or less than 40 nm.

18. The photo mask according to claim 13, wherein the first region includes a dummy pattern and a space width is constant.
